(19) United States
(12) Patent Application Publication
(10) Pub. No.: US 2010/0315097 A1
(43) Pub. Date: Dec. 16, 2010

(54) AMPLIFIER CIRCUIT

(76) Inventor: John Paul Lesso, Edinburgh (GB)

Correspondence Address: DICKSTEIN SHAPIRO LLP, 1825 EYE STREET NW, Washington, DC, 20006-5403, US

(21) Appl. No.: 12/744,095

(22) PCT Filed: Dec. 23, 2008
(86) PCT No.: PCT/GB08/04258

§ 371 Date: Jun. 11, 2010

(30) Foreign Application Priority Data
Dec. 28, 2007 (GB) 0725343.8

(51) Int. Cl. G01R 27/00

(52) U.S. Cl. 324/600

(57) ABSTRACT

An amplifier circuit comprises an amplifier for amplifying an input signal and outputting the amplified signal to an external device. A power supply provides a supply voltage to the amplifier. The nature or type of external device (for example line-load or headphones) is determined by measuring a parameter related to the supply voltage. The parameter may be the time taken for the supply voltage to fall or rise a predefined threshold value. Alternatively, the measured parameter may be a voltage drop or voltage rise over a predetermined period of time. Both of these parameters give an indication as to the rate of change of the supply voltage with time, which provides an indication of the nature of the load. Processing circuitry may be provided for calibrating the rate of change of the supply voltage with time, based on the input signal.

The present invention relates to amplifiers, and in particular, but not exclusively, to an audio amplifier apparatus and a method for determining a characteristic of an output device connected to the audio amplifier.

### BACKGROUND

Portable, and therefore battery operated, audio systems have become hugely popular over the last twenty years. Solid state audio devices such as MP3 players are the latest product in a line of portable music players that has included cassette players, CD players, minidisc players, etc. Further, mini TVs and DVD players integrated with a flat screen are now available so that users can watch films whilst travelling for example. Such portable systems usually make use of headphones, earbuds or small speakers (hereinafter referred to either individually and/or collectively as “First Load”) to receive the output audio for a personal user audio experience.

However, in addition to listening to audio via their portable apparatus using a First Load whilst travelling, walking, jogging etc., many users also wish to use their portable apparatus to listen to audio in the home or the car for example via an external (to the portable apparatus in question) sound processing apparatus (hereinafter referred to as “Second Load”). For example, a user may store their entire music collection on the hard drive of their portable MP3 player (which may be integrated as part of a mobile communication apparatus for example). Therefore, due to such requirements for using different audio output transducers, i.e. First or Second Loads, many portable audio and communications apparatus etc., are capable of connection to, and operation with, first and second loads.

FIG. 1 illustrates a basic block diagram showing an example of an amplifier circuit 10.

Referring to FIG. 1, a voltage regulator 12 receives a unipolar input voltage V_{IN} and ground GND and outputs bipolar output voltages V_{P} and V_{N} that are preferably, but not necessarily, centered around the ground potential (GND), i.e. 0 v. Such a voltage regulator 12 could, for example, be a dual-mode charge pump as described in the applicant's co-pending UK patent application number 0625954.3 incorporated herein in its entirety by reference. Connected between the respective positive and negative output voltage terminals 14, 16 and the ground terminal (GND) are respective positive and negative reservoir capacitors 18 (C_{P}) and 20 (C_{N}). An audio signal S_{IN} is input to an amplifier 22, amplified, and an output signal S_{OUT} output to a load 24. The combination of the amplifier 22 and the load 24 is referred to as an amplifying block 26. The amplifier 22 is powered by the bipolar output voltages V_{P} and V_{N} which is advantageous for audio applications, especially portable audio applications, since there is no requirement for a level shift circuit, such as a d.c. blocking capacitor for example, to be inserted in the output signal S_{OUT} path which may be necessary if the amplifier 22 is supplied by a unipolar supply voltage (V_{OUT}). Such an advantage is known and understood by those skilled in the art.

It will be appreciated that for a stereo audio application there will be at least two respective input signals (S_{IN1}, S_{IN2}) and respective amplifying blocks 26₁, 26₂ but possibly, although not necessarily, only one regulator 12 and one pair of reservoir capacitors 18 (C_{P}) and 20 (C_{N}) as illustrated in FIG. 2.

If the load 24 is a headphone/earbud/speaker type load, i.e. a first load, its impedance R_{L1} is relatively low, typically between 4Ω and 32Ω. In this case, the regulator 12 operates in a first mode, providing relatively low supply voltages (V_{P}-V_{N}) to the amplifier 22, which are nonetheless sufficient to amplify the signal for the relatively small load 24.

If the load 24 is a “line-load”, i.e. a second load, as would be the case with an external home, in-car etc., sound system, then the second load impedance R_{L2} is relatively high compared to the first load impedance R_{L1}, typically between 1 kΩ and 10 kΩ. It is advantageous when outputting to a second load for the voltage of an audio output signal S_{OUT} from the power amplifier 22 to have a relatively large amplitude such as 1V_{RMS} (although professional type audio processing equipment could possibly use 2V_{RMS} or even 5V_{RMS} signal amplitudes) so that the input signal (S_{OUT}) to the external sound system (represented by the load 24) has a good signal-to-noise ratio (SNR), i.e. the signal (S_{OUT}) is as clean, dynamic and accurate as possible. That is, the external sound system will have its own amplifier and therefore in order to achieve the best range of amplification, minimum distortion etc., the signal (S_{OUT}) input to the external sound system (24) should be as large as possible. Therefore, the voltage regulator 12 would, in a second mode, be required to supply an adequate voltage (V_{P}-V_{N}) so as to output, without clipping, a relatively large amplitude output signal.

However, if the first load RL₁ is connected to the output terminal 28 of the amplifier 22, and the voltage regulator 12 is still operating in the second mode, then for small-medium amplitude output signals S_{OUT}, there would be a significant power loss within the amplifier 22. Therefore, in such a case, the dual mode regulator 12 is controlled by a control signal CTL such that the dual mode regulator 12 operates in a first mode wherein the positive and negative output voltages V_{P} and V_{N} in the first mode are less than those in the second mode. The first mode positive and negative output voltages could be a fraction of those in the second mode, for example half, i.e. V_{P}/2 and V_{N}/2. It will be appreciated that the relationship between first mode and second mode positive and negative output voltages would be dependant of the type of regulator employed.

For the remainder of this specification we shall assume that in the first mode, the positive and negative output voltages V_{P1} and V_{N1} output from the dual mode regulator 12 are half the positive and negative output voltages V_{P2} and V_{N2} output from the dual mode regulator 12 in mode 2.

Therefore, supplying the amplifier 22, when driving the lower impedance load R_{L1}, with a lower supply voltage (V_{P1}-V_{N1}) than the amplifier 22 supply voltage (V_{P2}-V_{N2}) used when driving the higher impedance load R_{L2} saves the unnecessary dissipation of power in the amplifier 22 and hence power consumed from the reservoir capacitors 18, 20 and regulator 12 supply V_{IN}. Such power consumption savings are advantageous when the system 10 is operating from a finite power supply, such as a battery for example.

Thus, in order to be able to reduce power dissipation, it is important to be able to determine the “nature” of the load 24 coupled to the amplifier circuit 10. That is to say, it is important to determine whether the load 24 is a line-load type load (R_{L2}) or a headphone/earbud/speaker type load (R_{L1}), i.e. determine whether the load 24 is a high impedance or low impedance, so that the regulator 12 can be operatively controlled so as to supply the appropriate output voltage(s) for a given load impedance i.e. type.

A known technique for detecting the type of load 24 connected to the amplifier 22 is to measure the current drawn by the load 24 when a test signal is input onto the amplifier circuit's signal path. As the test signal is predetermined, i.e. has known characteristics, the expected amount of current to be drawn by typical first and second loads, i.e. output transducers, will also be known or expected. Therefore, measuring the current drawn by the load 24 can be used to determine the impedance (R_{L}) of the load 24 and hence the driving amplifier's optimum supply voltage, i.e. V_{P1}-V_{N1} or V_{P2}-V_{N2}.

However, there are a number of disadvantages to this approach of measuring the current drawn by the load 24. One drawback for example relates to the fact that the circuitry required to detect the current drawn by the load 24 is complicated and may cause distortion to the audio signal because the detection circuitry is in the signal path. For example, if a small, say 0.1 Ω, sense resistor (not illustrated) is placed in series with the load between the amplifier output 28 and the load 24 then a voltage drop V_{DROP} will be introduced across the sense resistor. This voltage drop V_{DROP} may result in: lower efficiency; a smaller headroom for output signal swing; and reduced maximum output signal voltage swing. Furthermore, detecting the voltage drop V_{DROP} typically by means of a high impedance differential amplifier (not illustrated) will result in common-mode-rejection-ratio issues that would need to be compensated for. If the sense resistor is placed in series after the load 24, i.e. between the load 24 and ground, then, apart from issues described above, access to the low-side of the load 24 will be required. For an integrated circuit solution, this would require an extra pin which is disadvantageous.

Another drawback is that there is no clear methodology as to when is the best time to drive the test signal through the system. One method is to test the load 24 with a test signal when the system 10 is first switched on. However, only testing the load 24 during turn-on of the apparatus 10 does not allow for the load 24 to be altered from a high impedance load (R_{L2}) to a low impedance load (R_{L1}), or vice-versa, during normal operation. Furthermore, any test signal, whenever it is introduced into the signal path, may cause undesirable audible artefacts such as a “pop”, “click” or “beep” for example.

All of these disadvantages affect the system performance and/or the end-user's experience, and are therefore to be avoided.

### SUMMARY OF INVENTION

According to a first aspect of the present invention, there is provided an amplifier circuit comprising an amplifier for amplifying an input signal and outputting the amplified signal to an external device, a power supply for providing a supply voltage to the amplifier, and means for measuring a parameter related to the supply voltage, and for determining a characteristic of the external device based on the measured parameter.

According to a second aspect of the present invention, there is provided a method for determining a characteristic of an external device in an amplifier circuit comprising an amplifier for amplifying an input signal and outputting the amplified signal to the external device, the amplifier being powered by a supply voltage. The method comprises the steps of measuring a parameter related to the supply voltage; and determining a characteristic of the external device based on the measured parameter.

According to a further aspect of the invention, there is provided an amplifier circuit comprising an amplifier for amplifying an input signal and outputting the amplified signal to an external device, means for determining a characteristic of the external device using a reference signal, and an envelope detector for detecting an envelope of the input signal, and for providing a control signal to said means for determining a characteristic of the external device such that the input signal may be used as the reference signal.

According to a further aspect of the invention, there is provided a method of determining a characteristic of an external device in an amplifier circuit comprising an amplifier for amplifying an input signal and outputting the amplified signal to the external device. The method comprises the steps of determining a characteristic of the external device using a reference signal, and detecting an envelope of the input signal, and using the detected envelope of the input signal in the step of determining the characteristic of the external device such that the input signal may be used as the reference signal.

### BRIEF DESCRIPTION OF THE DRAWINGS

For a better understanding of the present invention, and to show more clearly how it may be carried into effect, reference will now be made, by way of example, to the following drawings, in which:

FIG. 1 shows a conventional amplifier circuit;

FIG. 2 shows a conventional amplifier circuit for stereo input signals;

FIG. 3 shows variation of supply voltage over time;

FIG. 4 shows an amplifier circuit according to an embodiment of the present invention;

FIG. 5 shows an amplifier circuit according to an embodiment of the present invention for stereo input signals;

FIG. 6 shows an amplifier circuit according to a further embodiment of the present invention;

FIG. 7 shows an amplifier circuit according to the further embodiment of the present invention, adapted for stereo input signals;

FIGS. 8a and 8b respectively illustrate for a given low impedance load: the output amplifier's input signal S_{IN}; and the load current I_{L} supplied to the load;

FIGS. 9a and 9b respectively illustrate for a given high impedance load: the output amplifier's input signal S_{IN}; and the load current I_{L} supplied to the load;

FIG. 10 shows decision circuitry for use in the amplifier circuit according to an embodiment of the present invention;

FIG. 11 shows decision circuitry for use in the amplifier circuit according to another embodiment of the present invention;

FIGS. 12a and 12b show a first charge pump suitable for use with any of the amplifiers of the present invention; and

FIGS. 13a and 13b show a second charge pump suitable for use with any of the amplifiers of the present invention.

### DETAILED DESCRIPTION

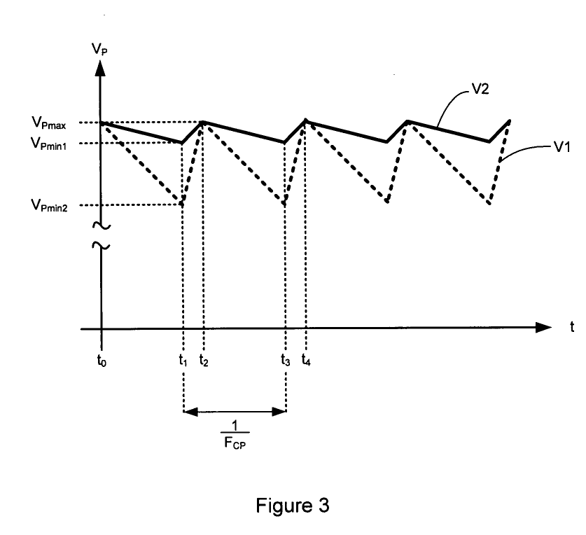

FIG. 3 is a schematic graph showing the idealised variation of the positive voltage V_{P} across the high-side reservoir capacitor 18 in the amplifier circuit 10. It will be appreciated that, although not illustrated for reasons of brevity, the negative voltage V_{N} across the low-side reservoir capacitor 20 in the amplifier circuit 10 varies in a similar, but opposite, fashion to that of the positive voltage V_{P}. The thicker dashed line V1 shows the variation of the positive voltage V_{P} when the load 24 is a lower impedance than that associated with the variation of the positive voltage V_{P} when the load 24 is a higher impedance as illustrated by the thicker solid line V2. Therefore, line V1 shows the variation of the positive voltage V_{P} when the load 24 is first type load (R_{L1}) and line V2 shows the variation of the positive voltage V_{P} when the load 24 is second type load (R_{L2}).

Assuming the charge pump regulator 12 is switched at a frequency F_{CP}, at time t₀ the charge pump 12 is switched off in the sense that the voltage across the storage capacitor 18 supplies all the power to the high-side of the amplifier 22.

Between t₀ and t₁, i.e. the discharge phase, the voltage V_{P} across the capacitor 18 drops for both types of load, i.e. first and second loads, as the reservoir capacitor 18 discharges i.e. as the amplifier 22 and load 24 each consume power. For a load 24 with a relatively high impedance (e.g. a second type load) the voltage V_{P} across the capacitor 18 discharges relatively slowly compared to a relatively low impedance (e.g. a first type load). Thus, the respective −dv/dt, i.e. discharge, characteristics of each of the loads R_{L1} and R_{L2} are different during the period between t₀ and t₁.

At time t₁ the charge pump 12 switches on in the sense that the input voltage V_{IN} charges up, via a pump capacitor (not illustrated) within the charge pump 12, and the storage capacitor 18 supplies power to the high-side of the amplifier 22.

Between t₁ and t₂, i.e. the charging phase, the voltage V_{P} across the capacitor 18 increases for both types of load, i.e. low and high impedance loads, as the reservoir capacitor 18 is charged from the pump capacitor. For a load 24 with a relatively high impedance (e.g. a second load) the voltage V_{P} across the capacitor 18 charges with a relatively smaller +dv/dt compared to a relatively low impedance (e.g. a first load). Thus, the respective +dv/dt, i.e. charging, characteristics of each of the loads R_{L1} and R_{L2} are different during the period between t₁ and t₂.

For both load types R_{L1}, R_{L2} the reservoir capacitor 18 V_{CP} is charged back to its initial value V_{P} at time t₂ and the whole cycle repeats itself for a given type of load.

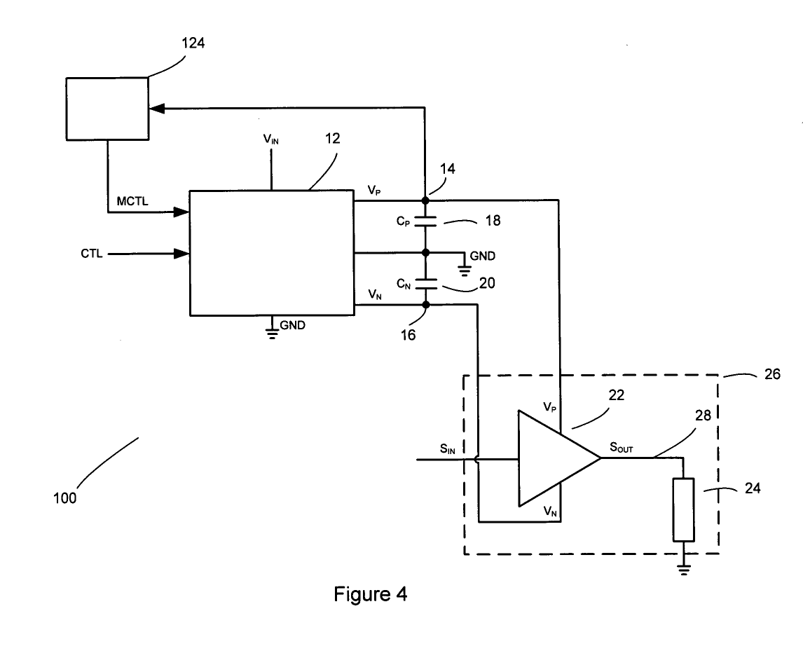

FIG. 4 shows an embodiment of an amplifier circuit 100 according to embodiments of the present invention.

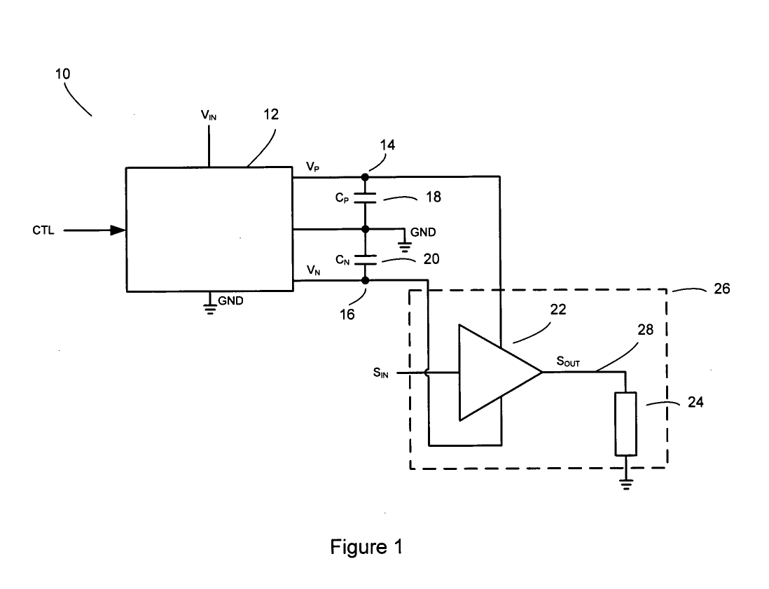

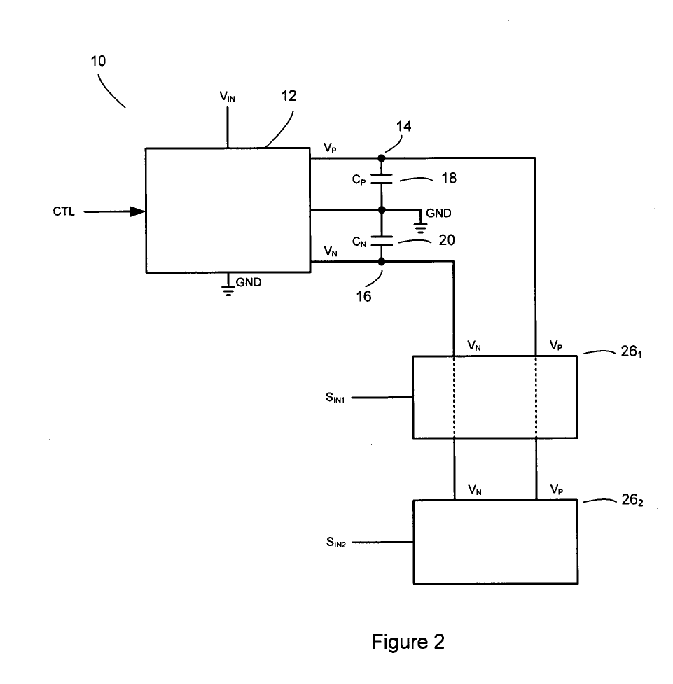

FIG. 4 illustrates the same arrangement as that illustrated and described in respect of FIG. 1 except that the amplifier 100 further comprises decision circuitry 124. According to one embodiment the decision circuitry 124 receives at least the positive output voltage V_{P} of the regulator 12. It is noted that, according to other embodiments (not shown), the decision circuitry could also be configured to receive the negative output voltage VN of the regulator 12, or just the negative output voltage V_{N} of the regulator 12. The decision circuitry 124 effectively monitors an output voltage (V_{P}/V_{N}) across a reservoir capacitor (C_{P}/C_{N}) in order to determine the nature of the load. The decision circuitry 124 outputs a mode control signal MCTL that controls the mode of the regulator 12 i.e. controls the value of the output voltage(s), depending upon the voltage across a reservoir capacitor. In other words, the decision circuitry 124 outputs a mode control signal MCTL that controls the mode of the regulator 12 depending upon a parameter associated with the load 24.

Therefore, according to embodiments of the present invention, the decision circuitry 124 may generally be used to measure a parameter related to a supply voltage V_{P}, V_{N} and to determine therefrom a characteristic of the load 24₁, 24₂, for example, whether the load is a high impedance, i.e. line-load, type load or a low impedance, i.e. headphone/earbud/speaker, type load.

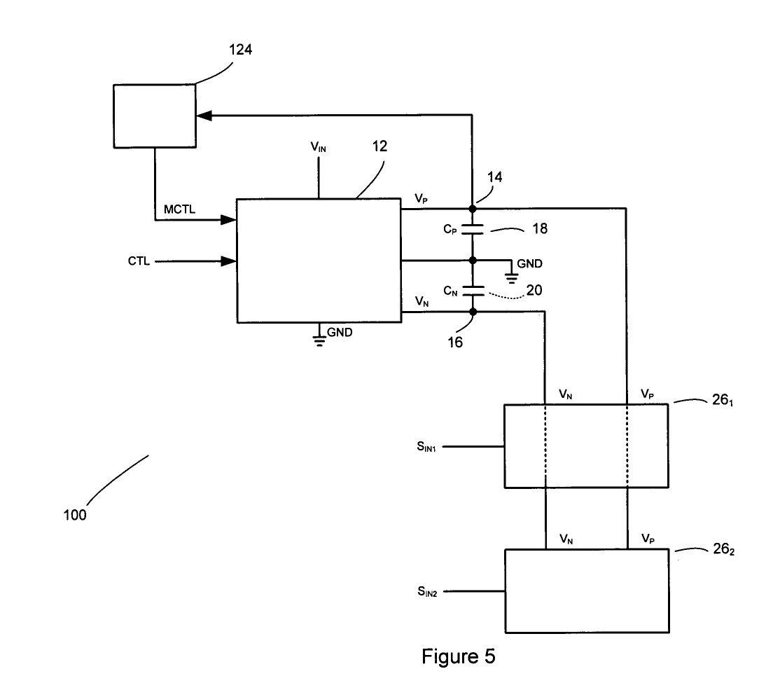

Again, it will be appreciated that for a stereo audio application for example, there will be at least two respective input signals (S_{IN1}, S_{IN2}) and amplifiers with loads 26₁, 26₂ but possibly, although not necessarily, only one regulator 12 and one pair of reservoir capacitors 18 (C_{P}) and 20 (C_{N}) as illustrated in FIG. 5.

One possible parameter related to a supply voltage output by the power supply 12 is the time taken for a voltage across one, or other, or both of the capacitors 18, 20 to fall to a predefined threshold value, or to fall by a predefined amount, i.e. measure the rate of change of the voltage across a capacitor dv/dt during the discharge phase. Alternatively, the measured parameter may be a voltage drop ΔV over a predetermined period of time t. Such parameters give an indication as to the rate of change of a voltage across a capacitor with time. One skilled in the art may think of many possible parameters or combinations without departing from the scope of the invention.

Alternatively, instead of determining a parameter relating to time taken for a voltage across a capacitor to fall a predefined threshold value, or a voltage to drop by a certain amount over a predetermined period of time etc, (for example during a discharge phase of a voltage regulator) one possible parameter may relate to the time taken for a voltage across a capacitor to rise to a predefined threshold value, or increase its voltage by a certain amount ΔV over a predetermined period of time or vice-versa (for example during a charging phase of a voltage regulator). Again, one skilled in the art may think of many possible parameters or combinations without departing from the scope of the invention.

Yet another alternative in determining the nature of a load 24 supplied by a voltage, provided by a switching type regulator 12, stored across a capacitor(s) would be to measure the duty cycle, switching frequency F_{CP} or other clocking signals associated with such a switching type regulator 12 to determine a characteristic of the type of load 24.

However, without a reference or test signal it may be difficult to determine how quickly the voltage across a capacitor should decay or rise or how the clocking signals are behaving. That is, in an audio application for example, when playing normally, the input signal S_{IN} to the power amplifier 22 will vary. If the signal S_{IN} has a relatively large amplitude, the load 24 will draw more current than if the signal S_{IN} has a relatively small amplitude, and therefore there is uncertainty in whether the relative rate of change of a capacitor voltage, or a change in the clocking signals, is due to the signal amplitude or a characteristic, i.e. impedance R_{L}, of the load 24.

One possible method to determine how quickly the voltage across a capacitor should decay or rise or how the clocking signals should behave is to play a known test signal S_{TEST} through the amplifier circuit 100. As the characteristics, such as amplitude, frequency etc., of the test signal S_{TEST} are known, the expected drop in a voltage across a capacitor, or its rate of change, or the expected clocking signals etc., would also be known, from previous characterisation and/or computation, for different load types. In such an embodiment, the decision circuitry 124 may comprise a look-up table (LUT) to compare the measured dv/dt, ΔV, Δt, duty cycle etc., with previously calibrated and/or calculated values. In this way, the nature of the load 24 can be determined. Such a test signal could, for example, have a frequency FS_{TEST} such that it is inaudible to the human ear i.e. FS_{TEST}>20 KHz or 20 Hz>FS_{TEST}. An advantage of such an inaudible test signal is that it can be injected into the signal path at any time. It would be preferable to use a test signal S_{TEST} that had a frequency FS_{TEST} that was equal to or greater than 20 KHz, as opposed to less than or equal to 20 Hz, so that the time taken to determine the type of load would be quicker.

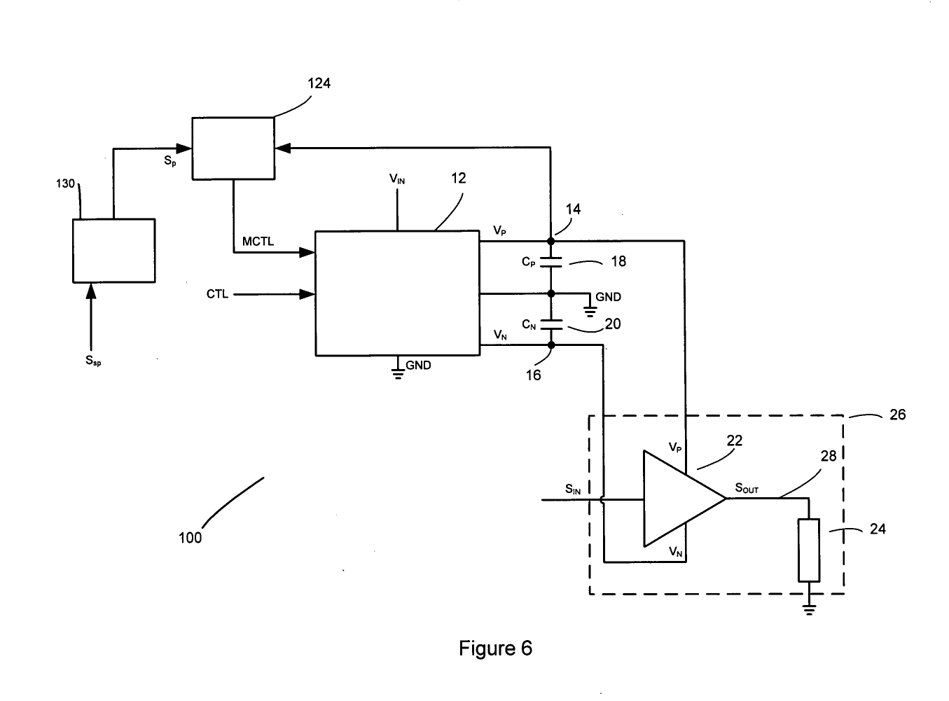

In another embodiment, illustrated in FIG. 6, the amplifier circuit 100 may comprise signal processing circuitry 130 to extract information from a signal S_{SP} in the signal path. It will be appreciated by those skilled in the art that circuitry in the signal path chain may take a number of different forms. For example, the circuitry in the signal path chain could be all analogue type circuitry and comprise one or more preamplifiers and/or filters etc., ahead of the output amplifier 22. Alternatively, the circuitry in the signal path chain could be all digital type circuitry, including the output amplifier 22 as would be the case in a Class D type amplifier. Yet another alternative is that the circuitry in the signal path chain could be a mixture of digital and analogue type circuitry and may comprise one or more analogue preamplifiers, a digital-to-analogue converter (DAC), a sigma-delta (ΣΔ) modulator, a digital filter etc. Such combinations of analogue, digital and mixed analogue/digital type circuitry being well known to those skilled in the art.

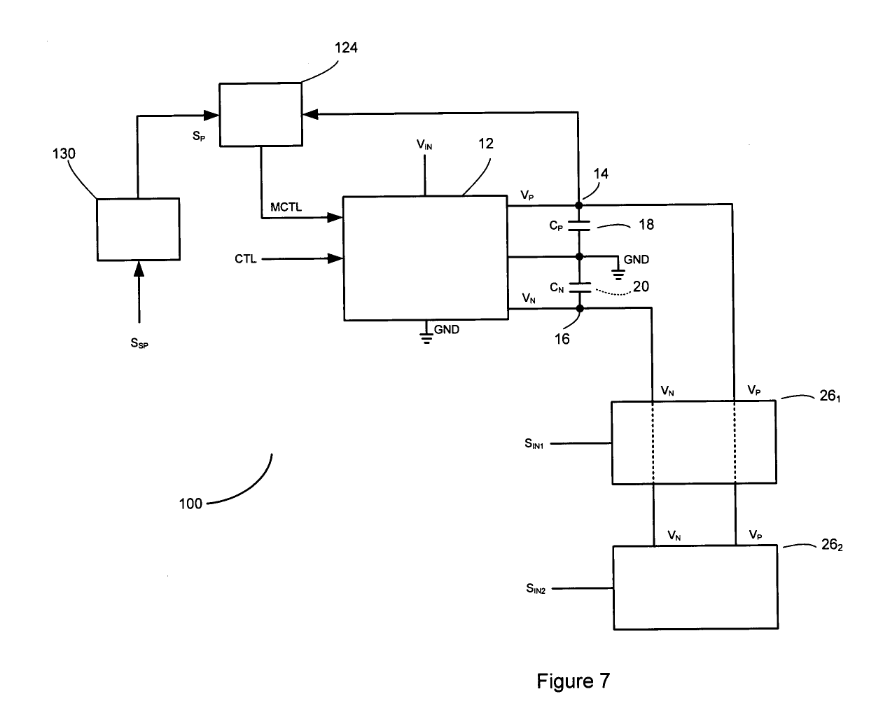

FIG. 7 illustrates the stereo audio application of FIG. 6 which also comprises signal processing circuitry 130 that receives a signal path signal S_{SP}.

The signal processing circuitry 130 may be for example an envelope detector which detects the envelope of the signal path signal S_{SP}. Alternatively the signal processing circuitry 130 may be an amplitude detector. The signal processing circuitry 130 provides a processed signal S_{P} to the decision circuitry 124 so the characteristics of the voltage across the capacitor can be correctly interpreted. For example, the processed signal S_{P} may be input to a LUT as well as the negative rate of change or decay of the capacitor voltage. As previously indicated, the signal path signal S_{SP} may be analogue or digital, and therefore the processing circuitry 130 may be a analogue, digital or mixed analogue and digital circuitry, as appropriate: likewise the processed signal S_{P} may be analogue or digital. In addition, as previously indicated, the invention may utilise the positive rate of change or rise of the capacitor voltage in conjunction with the processed signal S_{P} from the processing circuitry 130 to determine the nature of the load.

By measuring a characteristic of the input signal S_{IN} to the output amplifier 22 by means of a signal path signal S_{SP} (where S_{SP} may actually be S_{IN}) and comparing this to the output amplifier 22 supply voltage V_{P} across a capacitor 18 it is possible to avoid having to use a test type signal, i.e. a signal of predetermined amplitude, frequency etc. An advantage of using a signal path signal S_{SP} in determining a characteristic of the load 24 is that such load determination can be carried out at any time, either constantly or intermittently, without the need to generate or supply a test signal.

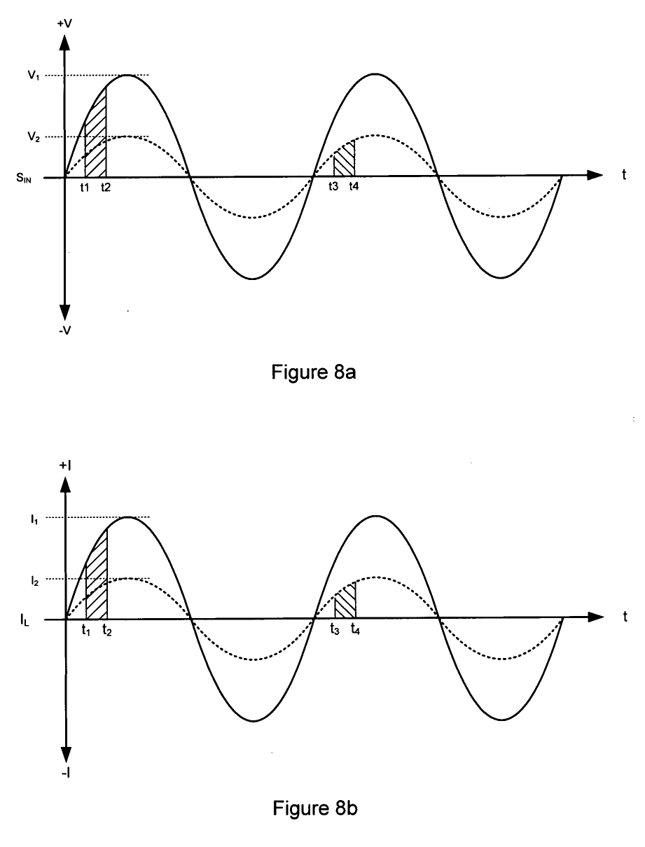

FIGS. 8a and 8b respectively illustrate for a given relatively low impedance load: the output amplifier's input signal S_{IN}; and the load current I_{L} supplied to the load 24, via the amplifier 22, from the reservoir capacitor 18. It will be appreciated that simple example sinusoidal waveforms have been chosen for the input signal in FIG. 8a for clarity of explanation.

FIG. 8a illustrates two example input signals S_{IN} each having different amplitudes V₁, V₂ but the same frequency. The larger amplitude signal is shown by the solid line and the smaller amplitude signal is shown by the dashed line.

FIG. 8b illustrates the amount of charge (ΔQ) that is taken from the reservoir capacitor 18 as a result of the two example input signals S_{IN} driving the amplifier 22. During the discharge period t₂-t₁, i.e. when only the capacitor 18 (C_{P}) supplies the amplifier 22, the larger amplitude I₁ signal (solid line) indicates that, for a given relatively low impedance load more charge is taken from the capacitor 18 than for the smaller amplitude 1₂ signal (dashed line) during a similar discharge period t₃-t₂. The amount of charge (ΔQ) that is taken from the reservoir capacitor 18 during a period Δt is given by:

ΔQ=IL.Δt=ΔV.C_{P}

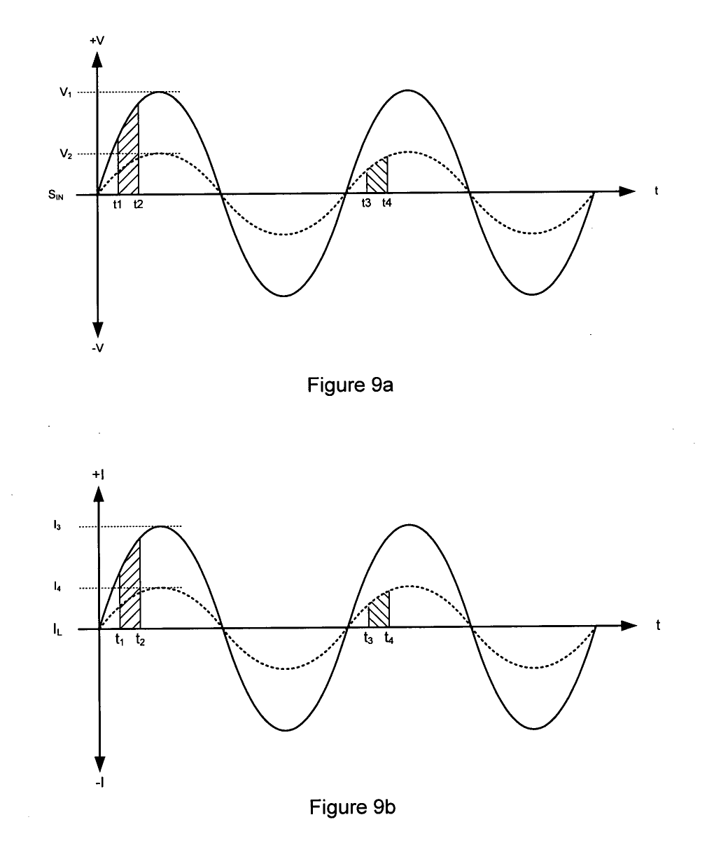

Likewise, FIGS. 9a and 9b respectively illustrate for a given relatively high impedance load: the output amplifier's input signal S_{IN}; and the load current I_{L} supplied to the load 24, via the amplifier 22, from the reservoir capacitor 18.

FIG. 9a illustrates two example input signals S_{IN} each having different amplitudes V₁, V₂ but the same frequency. Note that the values V₁ and V₂ are the same for both FIGS. 8a and 8b. The larger amplitude signal V₁ is shown by the solid line and the smaller amplitude V₂ signal is shown by the dashed line.

FIG. 9b illustrates the amount of charge (ΔQ) that is taken from the reservoir capacitor 18 as a result of the two example input signals S_{IN} driving the amplifier 22. During the discharge period t₂-t₁, i.e. when only the capacitor 18 (C_{P}) supplies the amplifier 22, the larger amplitude I₃ signal (solid line) indicates that, for a given relatively high impedance load more charge is taken from the capacitor 18 than for the smaller amplitude I₄ signal (dashed line) during a similar discharge period t₃-t₂. Note that the values I₁ and I₂ in FIG. 8b are both respectively greater the values I₃ and I₄ in FIG. 9b due to the different load types.

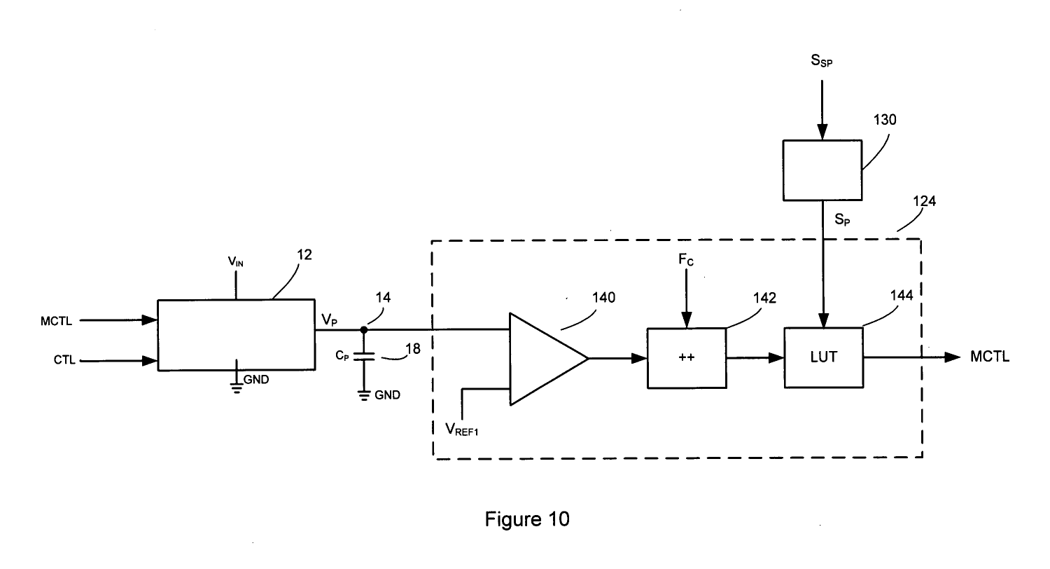

FIG. 10 shows one example of the decision circuitry 124. The playback path, i.e. signal path, of the amplifier circuit 100, i.e. the power amplifier 22, input signal and load 18 are not shown for reasons of clarity.

The power supply 12 charges the capacitor 18 as described previously. The voltage V_{P} across the capacitor 18 is input to a comparator 140 that compares the instantaneous capacitor voltage V_{PI} with a reference voltage V_{REF1}, where V_{REF1}=(V_{PX}−V_{TH1}) and where V_{PX} is the value of V_{P} at time t₀ or t₂, i.e. when the power supply 12 effectively switches off and stops charging the capacitor 18, and V_{TH1} is some predetermined threshold voltage value. A counter 142 receives a clock signal with frequency F_{C} and resets at times t₀, t₂, t₄ etc. The comparator 140 outputs a control signal to the counter 142 when V_{PI} falls below the reference voltage (V_{PX}−V_{TH}), so that the count value is latched. The count value then represents the time Δt taken for the voltage across the capacitor 18, V_{P}, to decrease by an amount ΔV. This count value is input to a look-up table (LUT) 144. In this embodiment, the processed signal S_{P} is also input to the LUT 144. The LUT 144 can then be used to determine the characteristic of the load 24, i.e. its load type, and output an appropriate regulator 12 control signal MCTL.

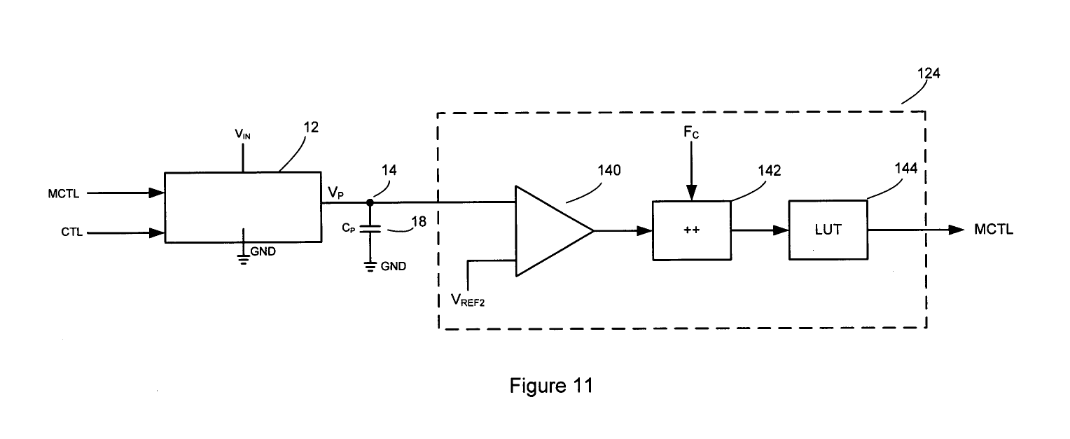

FIG. 11 shows an alternative embodiment of the decision circuitry 104 to that illustrated in respect of FIG. 10. Although FIGS. 10 and 11 show the decision circuitry being used with a regulator 12 providing an unipolar output voltage V_{P}, it is noted that the decision circuitry is also applicable to the bipolar arrangements shown in the other embodiments of the invention.

Referring to FIG. 11, again, the decision circuitry 104 comprises a comparator 140, a counter 142 operated at a frequency F_{C}, and a LUT 144. The comparator 140 compares the instantaneous capacitor voltage V_{PI} with a reference voltage V_{REF2} (where V_{REF2}=V_{PX}−V_{TH2}), where V_{PX} is the value of V_{P} at time t₀ or t₂, i.e. when the power supply 12 effectively switches off and stops charging the capacitor 18 and V_{TH2} is a threshold voltage. In this particular embodiment, the value of the threshold voltage V_{TH2} is controlled as a function of a signal path signal S_{SP}, or alternatively, a processed signal S_{P} from the processing circuit 130. Thus, if the signal path signal S_{SP}, or alternatively, the processed signal S_{P} has a relatively high value, i.e. amplitude for example, the value of V_{TH2} may be increased, so that the time taken for the voltage to fall by the voltage V_{TH2} is approximately the same, regardless of the signal amplitude. Similarly, if the signal value is relatively low, the value of V_{TH2} may be decreased. Therefore in this embodiment there is no need for the LUT 144 to receive any input signal other than that from the counter 142.

A person skilled in the art will appreciate that there are numerous ways in which the count value from the counter 142 and the processed signal S_{P}, or alternatively the signal path signal S_{SP}, may be used by the LUT 144 to map the count value and signal path signal S_{SP} to a given load.

Indeed a person skilled in the art will appreciate that there are numerous ways in which the voltage(s) across the capacitor(s) and/or the signal path signal(s) S_{SP} or processed signal S_{P} may be used either individually, together or with other signals, such as clocking signals, volume signals, control signals etc., or with other circuitry such as an analogue to digital converter (ADC) for example, or other alternative solutions or combinations so as to determine the type of load without departing from the scope of the invention as defined by the claims appended hereto.

Once the characteristic of the load 24 has been determined there are a number of possible responses. The decision circuitry 124 may set a flag in a register (not illustrated) so that other systems within or coupled to the amplifier 100 can adjust their operation accordingly. The decision circuitry 124 may limit the volume if headphone, or earphone or speaker type loads are detected, or automatically use the full volume setting if a line-load type load is detected. There are numerous examples and the invention is not limited to any one in particular.

The amplifiers described herein are preferably incorporated in an integrated circuit. For example, the integrated circuit may be part of an audio and/or video system, such as an MP3 player, a mobile phone, a camera or a satellite navigation system, and the system can be portable (such as a battery-powered handheld system) or can be mains-powered (such as a hi-fi system or a television receiver) or can be an in-car, in-train, or in-plane entertainment system. Further to the signals identified above, the signals amplified in the amplifier may represent ambient noise for use in a noise cancellation process.

Although the invention has been described in relation to detecting a load connected to a portable audio system, the invention is also applicable in the reverse situation, whereby a user wishes to attach headphones to a “fixed” audio system.

Those skilled in the art will appreciate that the regulator 12 may take one of many different forms.

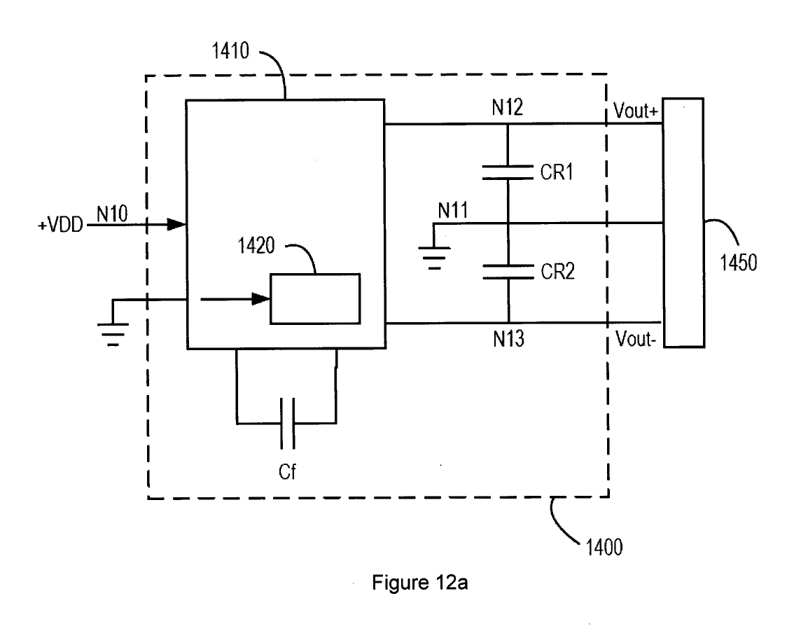

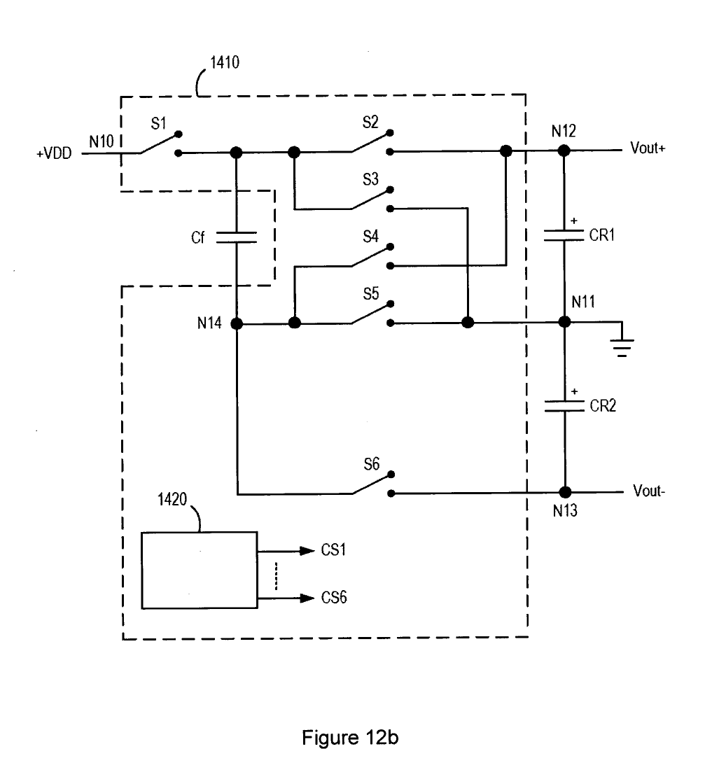

FIG. 12a shows a charge pump 1400 that is suitable for use as the voltage regulator 12.

FIG. 12a is a block diagram of a novel inverting charge pump circuit, which we shall call a “Level Shifting Charge-Pump” (LSCP) 1400. There are two reservoir capacitors CR1 and CR2, a flying capacitor Cf and a switch array 1410 controlled by a switch controller 1420. However, in this arrangement, neither of the reservoir capacitors CR1, CR2 are connected directly to the input supply voltage VDD, but only via the switch array 1410. It should be noted that LSCP 1400 is configured as an open-loop charge-pump, although a closed-loop arrangement would be readily appreciated and understood by those skilled in the art. Therefore, LSCP 1400 relies on the respective loads (not illustrated) connected across each output N12-N11, N13-N11 remaining within predetermined constraints. The LSCP 1400 outputs two voltages Vout+, Vout− that are referenced to a common voltage supply (node N11), i.e. ground. Connected to the outputs Vout+, Vout−, N11, and shown for illustration only, is a load 1450. In reality this load 1450 may be wholly or partly located on the same chip as the power supply, or alternatively it may be located off-chip. The load 1450 is a combination of the power amplifier 22 and the load 24.

LSCP 1400 operates such that, for an input voltage +VDD, the LSCP 1400 generates outputs of magnitude +VDD/2 and −VDD/2 although when lightly loaded, these levels will, in reality, be +/−VDD/2—Iload.Rload, where Iload equals the load current and Rload equals the load resistance. It should be noted that the magnitude (VDD) of output voltage across nodes N12 & N13 is the same, or is substantially the same, as that of the input voltage (VDD) across nodes N10 & N11.

FIG. 12b shows a more detailed version of the LSCP 1400 and, in particular, detail of the switch array 1410 is shown. The switch array 1410 comprises six switches S1-S6 each controlled by corresponding control signal CS1-CS6 from the switch controller 1420. The switches are arranged such that first switch S1 is connected between the positive plate of the flying capacitor Cf and the input voltage source, the second switch S2 between the positive plate of the flying capacitor and first output node N12, the third switch S3 between the positive plate of the flying capacitor and common terminal N11, the fourth switch S4 between the negative plate of the flying capacitor and first output node N12, the fifth switch S5 between the negative plate of the flying capacitor and common terminal N11 and the sixth switch S6 between the negative plate of the flying capacitor and second output terminal N13. It should be noted that the switches can be implemented in a number of different ways (for example, MOS transistor switches or MOS transmission gate switches) depending upon, for example, an integrated circuits process technology or the input and output voltage requirements.

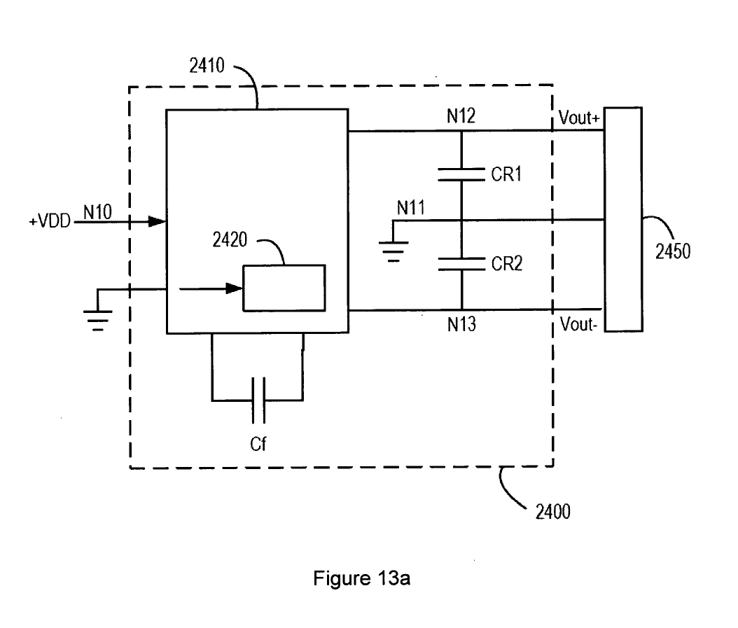

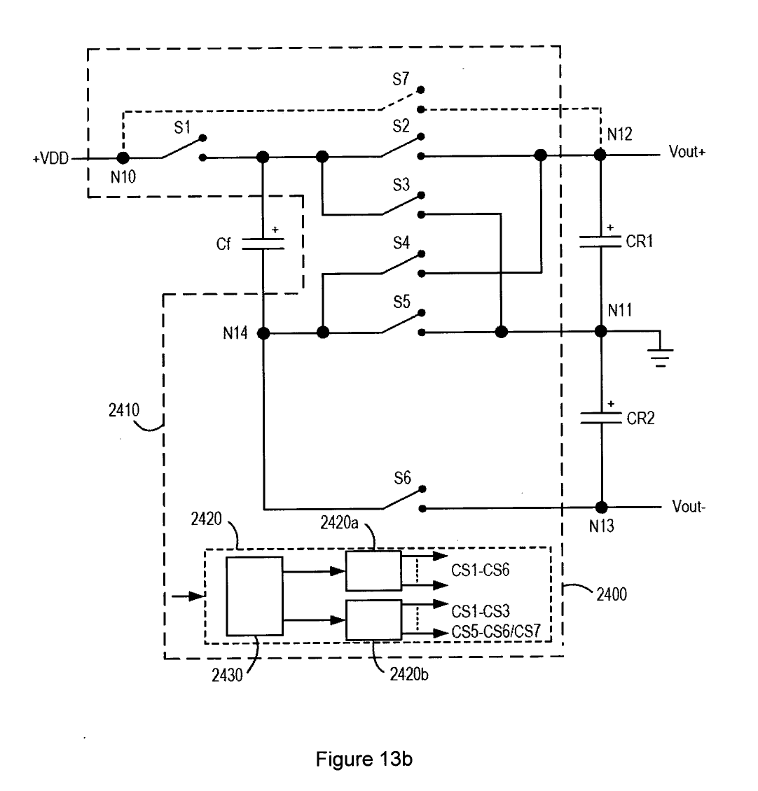

FIG. 13a shows a further charge pump 2400 that is suitable for use as the voltage regulator 12.

FIG. 13a is a block diagram of a novel inverting charge pump circuit, which we shall call a “Dual Mode Charge Pump” (DMCP) 2400. Again there are two reservoir capacitors CR1 and CR2, a flying capacitor Cf and a switch array 2410 controlled by a switch control module 420 (which may be software or hardware implemented). In this arrangement, neither of the reservoir capacitors CR1, CR2 are connected directly to the input supply voltage VDD, but rather via the switch array 2410.

It should be noted that DMCP 2400 is configured as an open-loop charge-pump, although a closed-loop arrangement would be readily appreciated and understood by those skilled in the art. Therefore, DMCP 2400 relies on the respective loads (not illustrated) connected across each output N12-N11, N13-N11 remaining within predetermined constraints. The DMCP 2400 outputs two voltages Vout+, Vout− that are referenced to a common voltage supply (node N11). Connected to the outputs Vout+, Vout−, N11, and shown for illustration only, is a load 2450. In reality this load 2450 may be wholly or partly located on the same chip as the power supply, or alternatively it may be located off-chip. The load 2450 is a combination of the power amplifier 22 and the load 24.

DMCP 2400 is operable in two main modes. In a first mode the DMCP 400 operates such that, for an input voltage +VDD, the DMCP 2400 generates outputs each of a magnitude which is a mathematical fraction of the input voltage VDD. In the embodiment below the outputs generated in this first mode are of magnitude +VDD/2 and −VDD/2, although when lightly loaded, these levels will, in reality, be +/−VDD/2—Iload.Rload, where Iload equals the load current and Rload equals the load resistance. It should be noted that, in this case, the magnitude (VDD) of output voltage across nodes N12 & N13 is the same, or is substantially the same, as that of the input voltage (VDD) across nodes N10 & N11. In a second mode the DMCP 400 produces a dual rail output of +/−VDD.

FIG. 13b shows a more detailed version of the DMCP 2400 and, in particular, detail of the switch array 2410 is shown. The switch array 2410 comprises six main switches S1-S6 each controlled by corresponding control signal CS1-CS6 from the switch control module 2420. The switches are arranged such that first switch S1 is connected between the positive plate of the flying capacitor Cf and the input voltage source, the second switch S2 between the positive plate of the flying capacitor and first output node N12, the third switch S3 between the positive plate of the flying capacitor and common terminal N11, the fourth switch S4 between the negative plate of the flying capacitor and first output node N12, the fifth switch S5 between the negative plate of the flying capacitor and common terminal N11 and the sixth switch S6 between the negative plate of the flying capacitor and second output node N13. Optionally, there may be provided a seventh switch S7 (shown dotted), connected between the input voltage source (node N10) and first output node N12. Also shown in greater detail is the control module 2420 which comprises mode select circuit 2430 for deciding which controller 2420a, 2420b or control program to use, thus determining which mode the DMCP operates in. Alternatively, the mode select circuit 2430 and the controllers 2420a, 2420b can be implemented in a single circuit block (not illustrated).

In the first mode, switches S1-S6 are used and the DMCP 2400 operates in a similar manner to the LSCP 1400. In the second mode, switches S1-S3 and S5-S6/S7 are used, and switch S4 is redundant.

It should be noted that the switches can be implemented in a number of different ways (for example, MOS transistor switches or MOS transmission gate switches) depending upon, for example, an integrated circuit's process technology or the input and output voltage requirements.

It will also be appreciated that the invention may be used, or adapted for use, with different forms of power supply unit 12, for example a battery, a buck converter, a boost converter and so forth.

In alternative embodiments, the regulator 12 could receive a unipolar input voltage V_{IN} and ground GND and output a unipolar output voltage V_{OUT} and ground GND for supplying the amplifier 22 whose output signal is preferably, but not necessarily, centered around the midpoint of the output voltage V_{OUT} and ground potential. In the case of a unipolar regulator, it may be necessary to include a level shift circuit or component, such as a d.c. blocking capacitor, in the output signal S_{OUT} path as will be readily appreciated.

In further embodiments, the regulator 12 may operate in more than two modes, supplying of more than two different supply voltages to the amplifier 22.

The skilled person will recognise that some of the above-described apparatus and methods may be embodied as processor control code, for example on a carrier medium such as a disk, CD- or DVD-ROM, programmed memory such as read only memory (firmware), or on a data carrier such as an optical or electrical signal carrier. For many applications, embodiments of the invention will be implemented on a DSP (digital signal processor), ASIC (application specific integrated circuit) or FPGA (field programmable gate array). Thus the code may comprise conventional program code or microcode or, for example code for setting up or controlling an ASIC or FPGA. The code may also comprise code for dynamically configuring re-configurable apparatus such as re-programmable logic gate arrays. Similarly the code may comprise code for a hardware description language such as Verilog™ or VHDL (very high speed integrated circuit hardware description language). As the skilled person will appreciate, the code may be distributed between a plurality of coupled components in communication with one another. Where appropriate, the embodiments may also be implemented using code running on a field-(re-)programmable analogue array or similar device in order to configure analogue/digital hardware.

It should be noted that the above-mentioned embodiments illustrate rather than limit the invention, and that those skilled in the art will be able to design many alternative embodiments without departing from the scope of the appended claims. The word “comprising” does not exclude the presence of elements or steps other than those listed in a claim, “a” or “an” does not exclude a plurality, and a single processor or other unit may fulfil the functions of several units recited in the claims. Any reference signs in the claims shall not be construed so as to limit their scope.

1. An amplifier circuit, comprising:
an amplifier for amplifying an input signal and outputting the amplified signal to an external device;
a power supply, for providing a supply voltage to the amplifier; and
means for measuring a parameter related to the supply voltage, and for determining a characteristic of the external device based on the measured parameter.

2. An amplifier circuit as claimed in claim 1, wherein the parameter is the time taken for the supply voltage to drop to a predetermined threshold.

3. An amplifier circuit as claimed in claim 1, wherein the parameter is the time taken for the supply voltage to drop by a predetermined amount.

4. An amplifier circuit as claimed in claim 1, wherein the parameter is the voltage drop of the supply voltage over a predetermined period of time.

5. An amplifier circuit as claimed in claim 1, wherein the parameter is the time taken for the supply voltage to rise to a predetermined threshold.

6. An amplifier circuit as claimed in claim 1, wherein the parameter is the voltage rise of the supply voltage over a predetermined period of time.

7. An amplifier circuit as claimed in claim 1, wherein the parameter is a rate of change of the supply voltage with time.

8. An amplifier circuit as claimed in claim 1, further comprising a look-up table, wherein the parameter is input to the look-up table to determine the characteristic of the external device.

9. An amplifier circuit as claimed in claim 1, wherein the characteristic is the impedance of the external device.

10. An amplifier circuit as claimed in claim 1, wherein the characteristic is the type of the external device.

11. An amplifier circuit as claimed in claim 9, wherein the type of the external device is a line-load or a set of passive speakers.

12. An amplifier circuit as claimed in claim 1, further comprising processing circuitry for detecting the input signal or a processed version of the input signal.

13. An amplifier circuit as claimed in claim 12, wherein the means for determining a characteristic of the external device is adapted to further determine the characteristic of the external device based on the detected input signal or a processed version of the input signal.

14. An amplifier circuit as claimed in claim 13, wherein the parameter is the time taken for the supply voltage to drop or rise to a predetermined threshold, and wherein the predetermined threshold is adapted based on the detected input signal.

15. An amplifier circuit as claimed in claim 13, wherein the parameter is the voltage drop or voltage rise of the supply voltage over a predetermined period of time, and wherein the predetermined period of time is adapted based on the detected input signal.

16. An amplifier circuit as claimed in claim 12, wherein said processing circuitry comprises an amplitude detector for measuring the amplitude of the input signal or a processed version of the input signal.

17. An amplifier circuit as claimed in claim 12, wherein said processing circuitry comprises an envelope detector for measuring the envelope of the input signal or a processed version of the input signal.

18. An amplifier circuit as claimed in claim 1, further comprising a capacitor, wherein said supply voltage is provided to the amplifier via the capacitor, and wherein said supply voltage is measured based on the voltage of the capacitor.

19. A method of determining a characteristic of an external device in an amplifier circuit comprising an amplifier for amplifying an input signal and outputting the amplified signal to the external device, the amplifier being powered by a supply voltage, the method comprising the steps of:
measuring a parameter related to the supply voltage; and
determining a characteristic of the external device based on the measured parameter.

20. A method as claimed in claim 19, wherein the parameter is the time taken for the supply voltage to drop or rise to a predetermined threshold.

21. A method as claimed in claim 19, wherein the parameter is the voltage drop or voltage rise of the supply voltage over a predetermined period of time.

22. A method as claimed in claim 19, wherein the parameter is a rate of change of the supply voltage with time.

23. A method as claimed in claim 19, further comprising the step of using the parameter to access a look-up table in order to determine the characteristic of the external device.

24. A method as claimed in claim 19, wherein the characteristic is the impedance of the external device.

25. A method as claimed in claim 19, wherein the characteristic is the type of the external device.

26. A method as claimed in claim 25, wherein the type of the external device is a line-load or a passive speaker.

27. A method as claimed in claim 19, further comprising the step of detecting the input signal or a processed version of the input signal.

28. A method as claimed in claim 27, wherein the step of determining a characteristic of the external device comprises the step of determining the characteristic of the external device based on the detected input signal.

29. A method as claimed in claim 28, wherein the parameter is the time taken for the supply voltage to drop or rise to a predetermined threshold, and further comprising the step of adapting the predetermined threshold based on the detected input signal.

30. A method as claimed in claim 28, wherein the parameter is the voltage drop or voltage rise of the supply voltage over a predetermined period of time, and further comprising the step of adapting the predetermined period of time based on the detected input signal.

31. A method as claimed in claim 27, wherein said detecting step comprises detecting the amplitude of the input signal or a processed version of the input signal.

32. A method as claimed in claim 27, wherein said detecting step comprises detecting the envelope of the input signal or a processed version of the input signal.

33. A method as claimed in claim 19, further comprising the step of providing a capacitor, wherein said supply voltage is provided to the amplifier via the capacitor, and wherein said supply voltage is measured based on the voltage of the capacitor.

34. An amplifier circuit, comprising:
an amplifier for amplifying an input signal and outputting the amplified signal to an external device; means for determining a characteristic of the external device using a reference signal; and
processing circuitry for detecting the input signal, and for providing a control signal to said means for determining a characteristic of the external device such that the input signal may be used as the reference signal.

35. An amplifier circuit as claimed in claim 34, wherein the means for determining a characteristic of the external device using a reference signal further comprises means for determining a current drawn in the external device when the input signal is used as a reference signal for driving the external device, the current drawn in the external device being indicative of the characteristic of the external device.

36. An amplifier circuit as claimed in claim 35, wherein the characteristic of the external device is determined according to the current drawn in the external device and the control signal from the processing circuitry.

37. An amplifier circuit as claimed in claim 36, further comprising a look-up table for determining the characteristic of the external device based on the current drawn in the external device and the control signal from the processing circuitry.

38. An amplifier circuit as claimed in claim 34, wherein said processing circuitry comprises an amplitude detector for measuring the amplitude of the input signal or a processed version of the input signal.

39. An amplifier circuit as claimed claim 34, wherein said processing circuitry comprises an envelope detector for measuring the envelope of the input signal or a processed version of the input signal.

40. A method of determining a characteristic of an external device in an amplifier circuit comprising an amplifier for amplifying an input signal and outputting the amplified signal to the external device, the method comprising the steps of;
determining a characteristic of the external device using a reference signal; and
detecting the input signal, and using the detected input signal in the step of determining the characteristic of the external device such that the input signal may be used as the reference signal.

41. A method as claimed in claim 40, wherein the step of determining a characteristic of the external device using a reference signal further comprises the step of measuring a current drawn in the external device when the input signal is used as a reference signal for driving the external device, the current drawn in the external device being indicative of the characteristic of the external device.

42. A method as claimed in claim 41, wherein the characteristic of the external device is determined according to the current drawn in the external device and the control signal from the processing circuitry.

43. A method as claimed in claim 42, further comprising the step of providing a lookup table for determining the characteristic of the external device based on the current drawn in the external device and the control signal from the processing circuitry.

44. A method as claimed in claim 40, wherein said detecting step comprises detecting the amplitude of the input signal or a processed version of the input signal.

45. A method as claimed claim 40, wherein said detecting step comprises detecting the envelope of the input signal or a processed version of the input signal.

46. An integrated circuit, comprising an amplifier circuit as claimed in claim 1.

47. An audio system, comprising an integrated circuit as claimed in claim 46.

48. An audio system as claimed in claim 47, wherein the audio system is a portable device.

49. An audio system as claimed in claim 47, wherein the audio system is a mains-powered device.

50. An audio system as claimed in claim 47, wherein the audio system is an in-car, in-train, or in-plane entertainment system.

51. A video system, comprising an integrated circuit as claimed in claim 46.

52. A video system as claimed in claim 51, wherein the video system is a portable device.

53. A video system as claimed in claim 51, wherein the video system is a mains-powered device.

54. A video system as claimed in claim 51, wherein the video system is an in-car, in-train, or in-plane entertainment system.
